(19) United States
(12) Patent Application Publication
(10) Pub. No.: US 2025/0175129 A1
(43) Pub. Date: May 29, 2025

(54) SEMICONDUCTOR DEVICE AND DOHERTY AMPLIFIER CIRCUIT

(71) Applicant: SUMITOMO ELECTRIC DEVICE INNOVATIONS, INC., Yokohama-shi (JP)

(72) Inventor: Seiya TAKASHIMA, Yokohama-shi (JP)

(73) Assignee: SUMITOMO ELECTRIC DEVICE INNOVATIONS, INC., Yokohama-shi (JP)

(21) Appl. No.: 18/956,816

(22) Filed: Nov. 22, 2024

(30) Foreign Application Priority Data
Nov. 27, 2023 (JP) 2023-200008

(51) Int. Cl. H03F 1/56; H03F 1/02; H03F 3/213

(52) U.S. Cl. CPC H03F 1/56; H03F 1/0288; H03F 3/213; H03F 2200/222; H03F 2200/387

(57) ABSTRACT

A semiconductor device includes a package that includes a base and an output lead, a first semiconductor chip that includes a main amplifier and a first output pad for outputting an amplified first signal, a second semiconductor chip that includes a first peak amplifier and a second output pad for outputting an amplified second signal, a third semiconductor chip includes a second peak amplifier and a third output pad for outputting an amplified third signal, a first impedance converter that has a first end connected to the first output pad and the output lead, and a second end connected to the second output pad and the third output pad, a first matching circuit that matches impedances of the first output pad and the first end with each other, and a second matching circuit matches impedances of the second output pad and the second end with each other.

### CROSS REFERENCE TO RELATED APPLICATIONS

This application claims priority based on Japanese Patent Application No. 2023-200008 filed on Nov. 27, 2023, and the entire contents of the Japanese patent applications are incorporated herein by reference.

### FIELD OF THE INVENTION

A certain aspect of the embodiments is related to a semiconductor device and a Doherty amplifier circuit.

### BACKGROUND OF THE INVENTION

There has been known an N (N is 3 or more)-way Doherty amplifier circuit using a main amplifier and two or more peak amplifiers (for example, Patent Documents 1 and 2). The N-way Doherty amplifier circuit includes an impedance converter for electrically connecting an output terminal of the main amplifier and an output terminal of the first peak amplifier, and an impedance converter for electrically connecting the output terminal of the main amplifier and an output terminal of the second peak amplifier (for example, Patent Document 1: U.S. Pat. No. 8,022,760, and Patent Document 2: U.S. Pat. No. 10,601,375).

### SUMMARY OF THE INVENTION

A semiconductor device according to the present disclosure includes: a package that includes a base and an output lead; a first semiconductor chip that is mounted on the base and includes a main amplifier for amplifying a first signal into which an input signal is divided and a first output pad for outputting an amplified first signal; a second semiconductor chip that is mounted on the base and includes a first peak amplifier for amplifying a second signal into which the input signal is divided and a second output pad for outputting an amplified second signal; a third semiconductor chip that is mounted on the base and includes a second peak amplifier for amplifying a third signal into which the input signal is divided and a third output pad for outputting an amplified third signal; a first impedance converter that is mounted on the base, and has a first end electrically connected to the first output pad and the output lead, and a second end electrically connected to the second output pad and the third output pad; a first matching circuit that is mounted on the base, and matches impedances of the first output pad and the first end with each other; and a second matching circuit that is mounted on the base, and matches impedances of the second output pad and the second end with each other.

### BRIEF DESCRIPTION OF DRAWINGS

FIG. 1 is a block diagram of a Doherty amplifier circuit according to a first embodiment.

FIG. 2 is a diagram illustrating a drain efficiency with respect to an input power of each amplifier in the first embodiment.

FIG. 3 is a circuit diagram of the Doherty amplifier circuit according to the first embodiment.

FIG. 4 is a circuit diagram of a subsequent stage of a transistor in the first embodiment.

FIG. 5 is a plan view of a semiconductor device according to the first embodiment.

FIG. 6 is a cross-sectional view taken along a line A-A of FIG. 5.

FIG. 7 is a plan view of a part of a semiconductor device according to the first embodiment.

FIG. 8 is an equivalent circuit diagram of FIG. 7.

FIG. 9 is a plan view of a part of a semiconductor device according to s first comparative example.

FIG. 10 is an equivalent circuit diagram of FIG. 9.

FIG. 11 is a plan view of a part of a semiconductor device according to a second comparative example.

FIG. 12 is an equivalent circuit diagram of FIG. 11.

FIG. 13 is a plan view of a part of a semiconductor device according to a third comparative example.

FIG. 14 is an equivalent circuit diagram of FIG. 13.

FIG. 15 is a plan view of a circuit substrate in the first comparative example.

FIG. 16 is a plan view of a circuit substrate in the first embodiment.

FIG. 17 is a plan view of a semiconductor device illustrating alternative example of the impedance converter in the first embodiment.

FIG. 18 is a circuit diagram illustrating alternative example of the impedance converter in the first embodiment.

FIG. 19 is a plan view illustrating a first alternative example of the matching circuit in the first embodiment.

FIG. 20 is an equivalent circuit diagram of FIG. 19.

FIG. 21 is a plan view illustrating a second alternative example of the matching circuit in the first embodiment.

FIG. 22 is an equivalent circuit diagram of FIG. 21.

FIG. 23 is a plan view illustrating a third alternative example of the matching circuit in the first embodiment.

FIG. 24 is an equivalent circuit diagram of FIG. 23.

FIG. 25 is a plan view illustrating a fourth alternative example of the matching circuit in the first embodiment.

FIG. 26 is an equivalent circuit diagram of FIG. 25.

### DETAILED DESCRIPTION

However, it is difficult to realize the matching circuit for matching the impedances between the main amplifier and the impedance converter with each other and the matching circuit for matching the impedances between the first peak amplifier and the impedance converter with each other.

The present disclosure has been made in view of the above problems, and an object of the present disclosure is to realize matching circuits in the N-way Doherty amplifier circuit.

### DETAILS OF EMBODIMENTS OF THE PRESENT DISCLOSURE

First, the contents of the embodiments of this disclosure are listed and explained.
(1) A semiconductor device according to the present disclosure includes: a package that includes a base and an output lead; a first semiconductor chip that is mounted on the base and includes a main amplifier for amplifying a first signal into which an input signal is divided and a first output pad for outputting an amplified first signal; a second semiconductor chip that is mounted on the base and includes a first peak amplifier for amplifying a second signal into which the input signal is divided and a second output pad for outputting an amplified second signal; a third semiconductor chip that is mounted on the base and includes a second peak amplifier for amplifying a third signal into which the input signal is divided and a third output pad for outputting an amplified third signal; a first impedance converter that is mounted on the base, and has a first end electrically connected to the first output pad and the output lead, and a second end electrically connected to the second output pad and the third output pad; a first matching circuit that is mounted on the base, and matches impedances of the first output pad and the first end with each other; and a second matching circuit that is mounted on the base, and matches impedances of the second output pad and the second end with each other. This makes it possible to realize the first matching circuit and the second matching circuit for an N-way Doherty amplifier circuit having a low characteristic impedance.
(2) In the above (1), the semiconductor device further may include: a second impedance converter that is mounted on the base, and has a third end electrically connected to the second end of the first impedance converter, and a fourth end electrically connected to the third output pad; and a third matching circuit that matches impedances of the third output pad and the fourth end with each other. This makes it possible to realize the third matching circuit and the second matching circuit having low characteristic impedances.
(3) In the above (1) or (2), the first end may be electrically connected to the first output pad via a first bonding wire, and the first end may be electrically connected to the output lead via a second bonding wire. This allows the first bonding wire to be used as a part of the first matching circuit.
(4) In the above (3), the second end may be electrically connected to the second output pad via a third bonding wire. This allows the third bonding wire to be used as a part of the second matching circuit.
(5) In the above (2), the first end may be electrically connected to the first output pad via a first bonding wire, the second end may be electrically connected to the output lead via a second bonding wire, the second end and the third end may be electrically connected to the second output pad through a third bonding wire, and the fourth end may be electrically connected to the third output pad via a fourth bonding wire. This allows the first, third and fourth bonding wires to be used as parts of the first, second and third matching circuits, respectively.
(6) In any one of the above (1) to (5), the semiconductor device further may include a line component including a dielectric substrate mounted on the base and a line pattern provided on the dielectric substrate. The first impedance converter may include the line pattern. This makes it possible to achieve the characteristic impedance and the electrical length of the first impedance converter with high accuracy.
(7) In any one of the above (1) to (5), the semiconductor device further may include: a first capacitor that is mounted on the base and has a first end electrically connected to the base; a second capacitor that is mounted on the base and has a first end electrically connected to the base; and a fifth bonding wire that electrically connects a second end of the first capacitor to a second end of the second capacitor. The first impedance converter may include the first capacitor, the second capacitor, and the fifth bonding wire. Thus, the first impedance converter can be formed.
(8) In any one of the above (1) to (7), the first impedance converter may shift a phase of a center frequency of an operating band by 90° between the first end and the second end. Thus, the first impedance converter can convert an impedance on the real axis of the Smith chart into a different impedance on the real axis.
(9) In the above (8), the first matching circuit may shift the phase of the center frequency by 90° between a signal source of the main amplifier and the first end, and the second matching circuit may shift the phase of the center frequency by 90° between a signal source of the first peak amplifier and the second end. This allows the impedance converter including the first and second matching circuits to convert an impedance on the real axis of the Smith chart into a different impedance on the real axis.
(10) In the above (2) or (5), the first impedance converter may shift a phase of a center frequency of an operating band by 90° between the first end and the second end, the second impedance converter may shift a phase of a center frequency of an operating band by 90° between the third end and the fourth end, the first matching circuit may shift the phase of the center frequency by 90° between a signal source of the main amplifier and the first end, the second matching circuit may shift the phase of the center frequency by 90° between a signal source of the first peak amplifier, and the second end and the third end, and the third matching circuit may shift the phase of the center frequency by 90° between a signal source of the second peak amplifier and the fourth end. This allows the first and the second impedance converters and the impedance converter including the first and second matching circuits to convert an impedance on the real axis of the Smith chart into a different impedance on the real axis.
(11) In any one of the above (1) to (10), an input power for turning on the first peak amplifier may be larger than an input power for turning on the main amplifier, and an input power for turning on the second peak amplifier may be larger than the input power for turning on the first peak amplifier. This makes it possible to realize a Doherty amplifier circuit.
(12) In any one of the above (1) to (11), an angle formed between a direction in which the amplified first signal flows and a direction in which the amplified second signal flows may be 70° or more and 110° or less at the first end. This allows the size of the device to be reduced.
(13) A semiconductor device according to the present disclosure includes: the semiconductor device according to any one of the above (1) to (12); and a divider that divides the input signal into the first signal, the second signal, and the third signal. This makes it possible to realize a Doherty amplifier circuit.

Specific examples of a semiconductor device and a Doherty amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

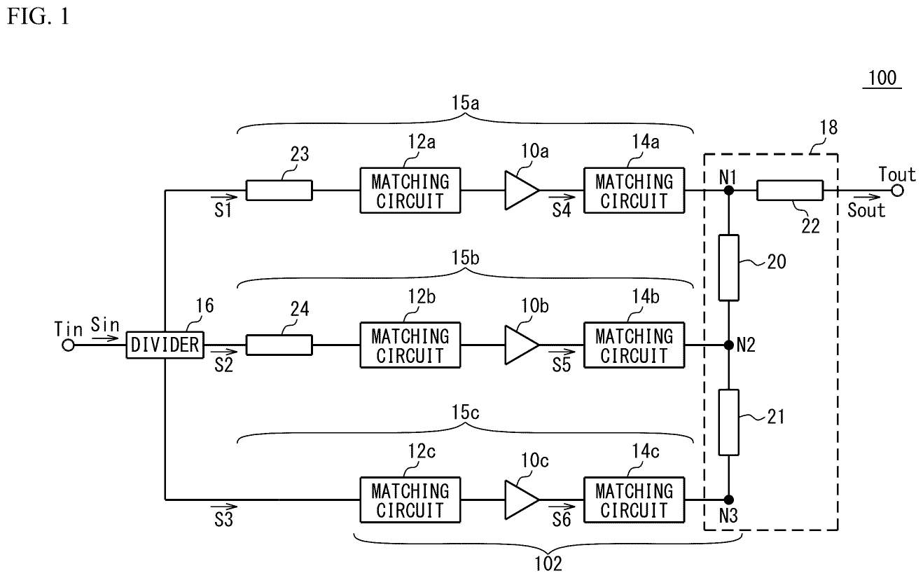

As an example of the Doherty amplifier circuit, a description will be given of a high-output high-frequency amplifier circuit used in a base station of mobile communication. In this case, the frequency of the high-frequency signal is, for example, 0.5 GHz or more and 10 GHz or less. FIG. 1 is a block diagram of the Doherty amplifier circuit according to a first embodiment. In FIG. 1, a bias circuit for supplying a bias voltage to a main amplifier 10a and peak amplifiers 10b and 10c is not illustrated.

As illustrated in FIG. 1, a Doherty amplifier circuit 100 is provided with three paths 15a to 15c in parallel between a divider 16 and a combiner 18. A high-frequency signal is input to an input terminal Tin as an input signal Sin. The divider 16 divides the input signal Sin input to the input terminal Tin into the signals S1 (first signal), S2 (second signal), and S3 (third signal). The divider 16 is, for example, a Wilkinson-type divider. Thus, the Doherty amplifier circuit 100 is a three-way amplifier circuit. The Doherty amplifier circuit 100 may be an N-way Doherty amplifier circuit having N paths 15a to 15c, that is, three or more paths.

The signals S1 through S3 pass through paths 15a through 15c, respectively. The path 15a includes a phase adjuster 23, a matching circuit 12a, the main amplifier 10a, and a matching circuit 14a (first matching circuit). The path 15b includes a phase adjuster 24, a matching circuit 12b (second matching circuit), the peak amplifier 10b, and a matching circuit 14b. The path 15c includes a matching circuit 12c (third matching circuit), the peak amplifier 10c, and a matching circuit 14c.

Phase adjusters 23 and 24 adjust a phase between paths 15a through 15c. The matching circuits 12a to 12c match the impedances seen from the divider 16 toward the matching circuits 12a to 12c with the impedances seen from the matching circuits 12a to 12c toward the main amplifier 10a, the peak amplifier 10b (first peak amplifier), and the peak amplifier 10c (second peak amplifier), respectively.

The main amplifier 10a and the peak amplifiers 10b and 10c amplify the signals S1 to S3, respectively, and output the amplified signals S4 to S6, respectively. The matching circuits 14a to 14c match the impedances seen from the main amplifier 10a and the peak amplifiers 10b and 10c toward the matching circuits 14a to 14c with the impedances seen from the matching circuits 14a to 14c toward the nodes N1 to N3, respectively.

The combiner 18 includes impedance converters 20 to 22. The impedance converter 20 (first impedance converter) is connected between the nodes N1 and N2. The impedance converter 21 (second impedance converter) is connected between the nodes N2 and N3. The impedance converter 22 is connected between the node N1 and an output terminal Tout. The combiner 18 combines the signals S4 to S6 to each other and outputs the synthesized signal to the output terminal Tout as an output signal Sout.

The main amplifier 10a and the peak amplifiers 10b and 10c are, for example, FETs (Field Effect Transistors), and are, for example, GaN HEMT (Gallium Nitride High Electron Mobility Transistor) or LDMOS (Laterally Diffused Metal Oxide Semiconductor).

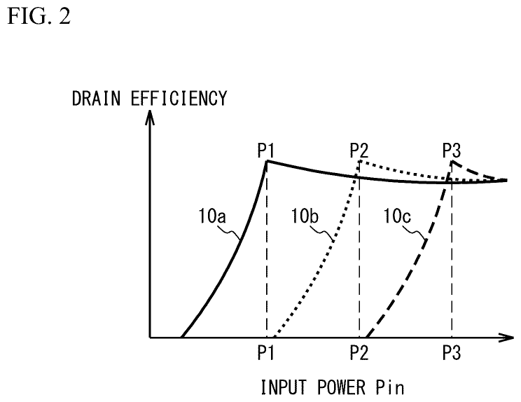

FIG. 2 is a diagram illustrating a drain efficiency with respect to an input power of each amplifier in the first embodiment. As illustrated in FIG. 2, when an input power Pin increases, the main amplifier 10a starts to operate. At a power P1 at which the drain efficiency of the main amplifier 10a is maximized, the peak amplifiers 10b and 10c are not operating. When the input power Pin becomes larger than the power P1, the peak amplifier 10b starts to operate in addition to the main amplifier 10a. The peak amplifier 10c is not operating at a power P2 at which the drain efficiency of the peak amplifier 10b is maximized. When the input power Pin becomes larger than the power P2, the peak amplifier 10c starts to operate in addition to the main amplifier 10a and the peak amplifier 10b. Thereafter, the drain efficiency of the peak amplifier 10c is maximized at a power P3. In this way, the input power at which the peak amplifier 10b is turned on is greater than the input power at which the main amplifier 10a is turned on, and the input power at which the peak amplifier 10c is turned on is greater than the input power at which the peak amplifier 10b is turned on. The main amplifier 10a is, for example, an A class or AB class amplifier, and the peak amplifiers 10b and 10c are, for example, C class amplifiers.

Conditions for the operation of the Doherty amplifier circuit 100 are as follows, as illustrated in FIG. 2.
Condition 1: At the power P1, the output power of the main amplifier 10a is saturated, and the peak amplifiers 10b and 10c are not operating.
Condition 2: At the power P2, the output powers of the main amplifier 10a and the peak amplifier 10b are saturated, and the peak amplifier 10c is not operating.
Condition 3: At the power P3, the output powers of the main amplifier 10a, the peak amplifier 10b, and the peak amplifier 10c are saturated.
Condition 4: The main amplifier 10a, the peak amplifier 10b, and the peak amplifier 10c are not supersaturated.
Condition 5: When the peak amplifiers 10b and 10c are not operating, the impedances seen from the node N1 toward the peak amplifiers 10b and 10c are open, and when the peak amplifier 10c is not operating, the impedance seen from the node N2 toward the peak amplifier 10c is open.

### [Description of Circuit Configuration]

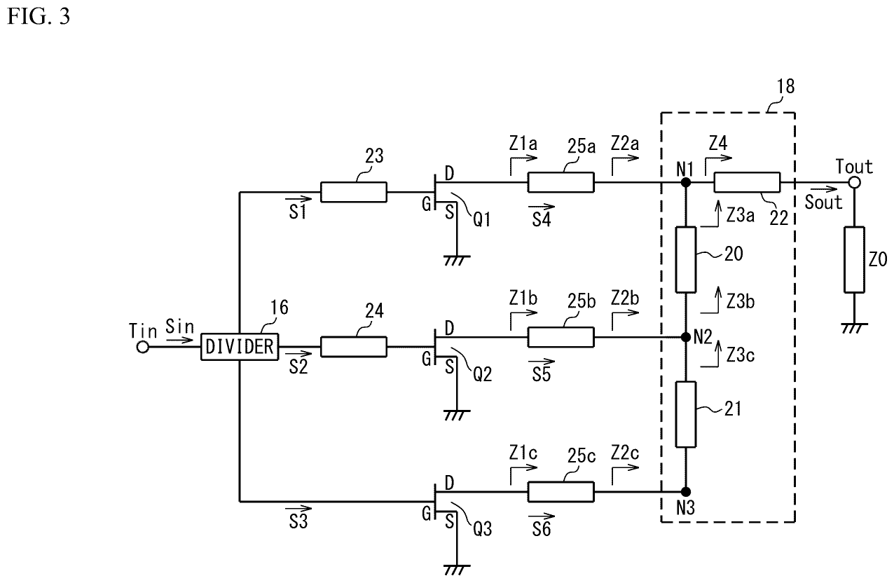

A circuit configuration satisfying the above conditions 1 to 5 will be described. FIG. 3 is a circuit diagram of the Doherty amplifier circuit according to the first embodiment. The matching circuits 12a to 12c are not illustrated.

As illustrated in FIG. 3, the main amplifier 10a and the peak amplifiers 10b and 10c are transistors Q1 to Q3. The sources S of the transistors Q1 to Q3 are grounded. The signals S1 to S3 are input to the gates G of the transistors Q1 to Q3, respectively. The signals S4 to S6 are output from the drains D of the transistors Q1 to Q3, respectively. Impedance converters 25a to 25c are connected between the drains D of the transistors Q1 to Q3 and the nodes N1 to N3, respectively.

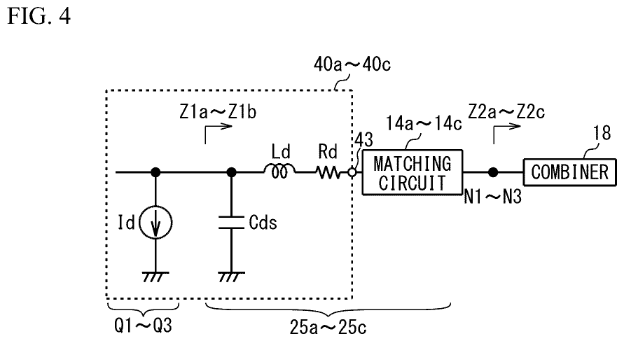

FIG. 4 is a circuit diagram of a subsequent stage of the transistor in the first embodiment. As illustrated in FIG. 4, the transistors Q1 to Q3 in FIG. 3 do not include the drain-source capacitance Cds, the drain inductance Ld, and the drain resistance Rd. The drain-source capacitance Cds is shunt-connected to the subsequent stage of the signal source Id, and the drain inductance Ld and the drain resistance Rd are connected in series. A drain resistor Rd is connected to pads 43 of semiconductor chips 40a to 40c described later. The matching circuits 14a to 14c are provided between the pad 43 and the nodes N1 to N3, respectively. The impedance converters 25a to 25c of FIG. 3 include the drain-source capacitance Cds, the drain inductance Ld, the drain resistance Rd, and the matching circuits 14a to 14c, respectively.

At the saturation powers of the transistors Q1 to Q3, a load impedance Zopt at which the output power is maximum (this is referred to as output matching) and a load impedance Zmod at which the efficiency is maximum (this is referred to as efficiency matching) are positioned on substantially a real axis on the Smith chart. That is, the reactance components of the load impedances Zopt and Zmod are substantially zero. For example, if a Doherty amplifier circuit is assumed in which the center frequencies of the operating bands are 2 GHz, the maximum output powers of the transistors Q1 to Q3 are 200 W and the maximum output power of the output signal Sout is 600 W, Zopt is about 2Ω and Zmod is Zopt×M (M is about 1 to 5).

The impedance converters 20 to 22 and 25a to 25c shift the phase at the center frequency of the operating band by 90°. Thus, the impedance located substantially on the real axis of the Smith chart is converted into an impedance located at a different position substantially on the real axis of the Smith chart. The characteristic impedances of the impedance converters 20 to 22 and 25a to 25c are set by the impedances before and after the conversion. For example, in a 2-way Doherty amplifier circuit, the phase may be shifted by 180° by the impedance converters 25b and 20. Since there is no node to which the peak amplifier 10c is connected, the impedance converters 25b and 20 need not be divided. On the other hand, in the N (N is 3 or more)-way Doherty amplifier circuit, the node N2 for electrically connecting the peak amplifier 10c exists between the impedance converters 20 and 25b. Therefore, the impedance converters 25b and 20 each having a phase shifted by 90° are separated from each other, and the node N2 is provided therebetween.

As illustrated in FIG. 3, the impedance converters 25a to 25c convert impedances Z1a to Z1c seen from the signal sources Id of the transistors Q1 to Q3 toward the impedance converters 25a to 25c into impedances Z2a to Z2c seen from the impedance converters 25a to 25c to the nodes N1 to N3, respectively. The impedance converter 20 converts an impedance Z3b seen from the node N2 toward the impedance converter 20 into an impedance Z3a seen from the impedance converter 20 toward the node N1. The impedance converter 21 converts the impedance Z2c seen from the node N3 toward the impedance converter 21 into an impedance Z3c seen from the impedance converter 22 toward the node N2. The impedance converter 22 converts the impedance Z4 seen from the node N1 toward the impedance converter 22 into the impedance Z0 seen from the impedance converter 22 toward the output terminal Tout.

For example, a description will be given of a case where the saturation power of the main amplifier 10a and the peak amplifiers 10b and 10c are the same as each other. At the power P3, the output powers of the main amplifier 10a and the peak amplifiers 10b and 10c are assumed to be the maximum powers Pmax. The following assumptions were made. At the power P2, the output power of the main amplifier 10a is Pmax/2, and the output power of the peak amplifier 10b is Pmax/4. At the power P1, the output power of the main amplifier 10a is Pmax/3. The output powers of the main amplifier 10a and the peak amplifiers 10b and 10c when the input powers Pin are the power P1 to P3, respectively, can be set as appropriate in addition to the above. Assume that the load impedance Z0 is 50Ω and the impedance Z4 is 16.7Ω. The load impedance Z0 and the impedance Z4 can also be set as appropriate. The configurations of the matching circuits 14a to 14c are assumed to be the same as each other. The configurations of the matching circuits 14a to 14c can be set as appropriate.

At the power P1, the impedance seen from the node N1 toward the impedance converter 20 is almost infinite, so the impedance Z2a is 16.7Ω and the same as the impedance Z4. The impedance converter 25a converts the impedance Z2a of 16.7Ω into the impedance Z1a of Zmod. This allows the main amplifier 10a to operate with efficiency matching.

At the power P2, the impedance Z4 of 16.7Ω is divided into the impedance Z2a of 25Ω and the impedance Z3a of 50Ω. The impedance converter 20 converts the impedance Z3a of 50Ω into the impedance Z3b of 12.5Ω. Since the impedance seen from the node N2 toward the impedance converter 21 is almost infinite, the impedance Z2b is 12.5Ω, which is the same as the impedance Z3b. At the power P2, the power of the main amplifier 10a and the peak amplifier 10b are Pmax/2 and Pmax/4, respectively. Therefore, in order to make the main amplifier 10a and the peak amplifier 10b have output-matching, the impedances Z1a and Z1b are 2×Zopt and 4×Zopt, respectively. The impedance converter 25a converts the impedance Z2a of 25Ω into the impedance Z1a of 2×Zopt. The impedance converter 25b converts the impedance Z2b of 12.5Ω into the impedance Z1b of 4×Zopt. This allows the main amplifier 10a and the peak amplifier 10b to operate with output matching.

At the power P3, the impedance Z4 of 16.7Ω is divided into the impedance Z2a of 50Ω and the impedance Z3a of 25Ω. The characteristic impedance of the impedance converter 20 is 25Ω, and the impedance converter 20 converts the impedance Z3a of 25Ω into the impedance Z3b of 25Ω. The impedance Z3b of 25Ω is divided into the impedance Z2b of 50Ω and the impedance Z2c of 50Ω. The characteristic impedance of the impedance converter 21 is 50Ω, and the impedance converter 21 converts the impedance Z3c of 50Ω into the impedance Z2c of 50Ω. In this way, the impedances Z2a to Z2c are all 50Ω. The impedance converters 25a to 25c convert the impedances Z2a to Z2c of 50Ω so that the impedances Z1a to Z1c are both equal to Zopt. This allows the main amplifier 10a and the peak amplifiers 10b and 10c to operate with output matching.

As described above, by using the impedance converters 20 to 22 and 25a to 25c, the Doherty amplifier circuit 100 can be operated as illustrated in FIG. 2. The phase adjusters 23 and 24 align the phases of signals S4 to S6 at the node N1. The phase adjuster 23 shifts the phase of the signal S1 by about 180°, for example. The phase adjuster 24 shifts the phase of the signal S2 by about 90°.

The semiconductor device used in the first embodiment will be described.

In FIG. 1, the Doherty amplifier circuit 100 is provided with the main amplifier 10a, the peak amplifiers 10b and 10c, the matching circuits 12a to 12c and 14a to 14c, and the impedance converters 20 and 21.

When the input powers Pin are the powers P1, P2, and P3, the characteristic impedances of the impedance converters 25a to 25c are about V (Zopt×Zmod) in order to achieve a well-balanced wide band. When Zopt is about 2Ω, the characteristic impedances of the impedance converters 25a to 25c are 2Ω to 4Ω. The remainders of the impedance converters 25a to 25c from which the drain-source capacitance Cds of FIG. 4 is removed are realized in the matching circuits 14a to 14c. For example, the matching circuits 14a to 14c are lines having characteristic impedances of 2Ω to 4Ω and phases of about 30° to 50°.

### [Description of Semiconductor Device]

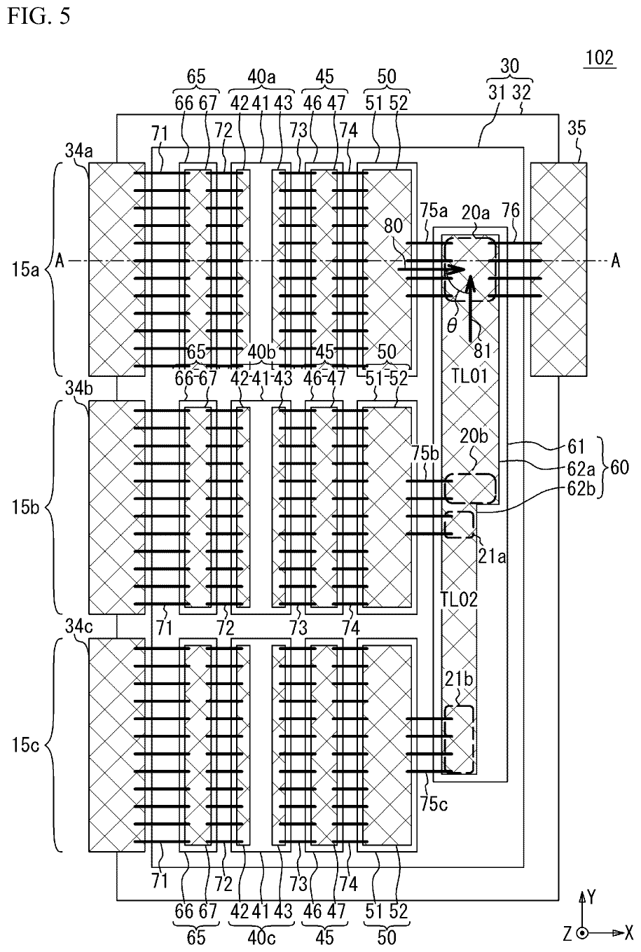

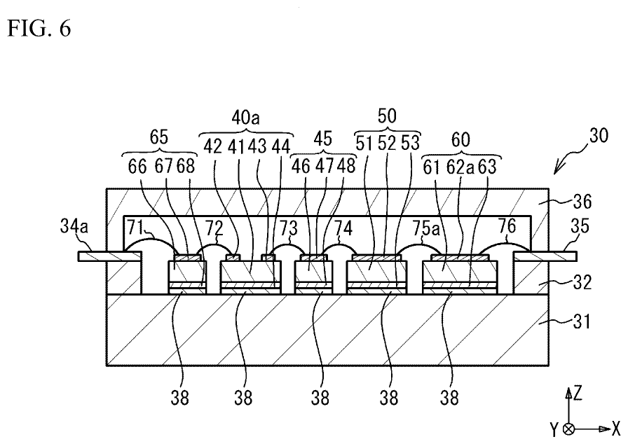

A semiconductor device for realizing such matching circuits 14a to 14c will be described. FIG. 5 is a plan view of the semiconductor device according to the first embodiment. FIG. 6 is a cross-sectional view taken along a line A-A in FIG. 5. A lid 36 is not illustrated in FIG. 5. A thickness direction of a base 31 is defined as a Z direction, a direction from a lead 34a to a lead 35 is defined as an X direction, and a direction orthogonal to the X direction and the Z direction is defined as a Y direction.

As illustrated in FIGS. 5 and 6, in a semiconductor device 102 of the first embodiment, a package 30 has the base 31 having at least an upper surface which is conductive, a frame 32, and the lid 36. The base 31 is a conductor substrate such as a laminated substrate of copper and molybdenum. A reference potential such as a ground potential is supplied to the base 31. The frame 32 and the lid 36 are dielectric layers made of, for example, a resin such as a glass epoxy resin or a ceramic. Semiconductor chips 40a to 40c, line components 45, high dielectric components 50, a line component 60, and capacitive components 65 are mounted on the base 31. The frame 32 is provided on the base 31 so as to surround the semiconductor chips 40a to 40c, the line components 45, the high dielectric components 50, the line component 60, and the capacitive components 65. The lid 36 is bonded to the upper surface of the frame 32 by an insulating adhesive (not illustrated) such as resin. The frame 32 and the lid 36 seal the semiconductor chips 40a to 40c in an air gap.

The planar shape of the frame 32 is substantially a rectangle. Leads 34a to 34c (input leads) are provided on the − side of the frame 32 in the X direction. The lead 35 (output lead) is provided on the + side of the frame 32 in the X direction. The leads 34a to 34c and 35 are metal layers such as copper or metal plates. The signals S1 to S3 are input to the leads 34a to 34c, respectively, and the output signal Sout is output from the lead 35.

The lead 34a, the capacitive component 65, the semiconductor chip 40a (first semiconductor chip), the line component 45, and the high dielectric component 50 are arranged in the X direction in correspondence with the path 15a. The lead 34b, the capacitive component 65, the semiconductor chip 40b (second semiconductor chip), the line component 45, and the high dielectric component 50 are arranged in the X direction in correspondence with the path 15b. The lead 34c, the capacitive component 65, the semiconductor chip 40c (third semiconductor chip), the line component 45, and the high dielectric component 50 are arranged in the X direction in correspondence with the path 15c. The line component 60 is mounted between the high dielectric component 50 and the frame 32 so as to extend in the Y direction.

Each of the semiconductor chips 40a to 40c includes a semiconductor substrate 41, pads 42 and 43 provided on the upper surface of the semiconductor substrate 41, and an electrode 44 provided on the lower surface of the semiconductor substrate 41. The pads 42 and 43 and the electrode 44 are a gate electrode, a drain electrode, and a source electrode, respectively, and the pad 42 is an input pad. The pads 43 of the semiconductor chips 40a, 40b, and 40c are a first output pad, a second output pad, and a third output pad, respectively. The transistors Q1 to Q3 illustrated in FIG. 3 are provided on the semiconductor substrate 41. When the transistors Q1 to Q3 are GaN HEMTs, the semiconductor substrate 41 is, for example, a silicon carbide (SiC) substrate, a sapphire substrate, or a gallium nitride (GaN) substrate. When the transistors Q1 to Q3 are LDMOS, the semiconductor substrate 41 is, for example, a silicon (Si) substrate. The pads 42, 43 and the electrodes 44 are metal layers, such as gold layers.

The capacitive component 65 includes a dielectric substrate 66, an electrode 67 provided on an upper surface of the dielectric substrate 66, and an electrode 68 provided on a lower surface of the dielectric substrate 66. The electrodes 67 and 68 interposing the dielectric substrate 66 form a capacitor. The dielectric substrate 66 is, for example, an alumina substrate or a barium titanate substrate. The electrodes 67 and 68 are metal layers, such as gold layers.

The line component 45 includes a dielectric substrate 46, a line pattern 47 provided on an upper surface of the dielectric substrate 46, and an electrode 48 provided on a lower surface of the dielectric substrate 46. The line pattern 47 and the electrode 48 form a transmission line. The dielectric substrate 46 is, for example, an alumina substrate. The line pattern 47 and the electrode 48 are metal layers such as gold layers.

The high dielectric component 50 includes a high dielectric substrate 51, an electrode 52 provided on an upper surface of the high dielectric substrate 51, and an electrode 53 provided on a lower surface of the high dielectric substrate 51. The electrodes 52 and 53 interposing the high dielectric substrate 51 form a capacitor. The high dielectric substrate 51 has a larger relative dielectric constant than an alumina substrate, such as a barium titanate substrate. The electrodes 52 and 53 are metal layers such as gold layers.

The line component 60 includes a dielectric substrate 61, line patterns 62a and 62b provided on the upper surface of the dielectric substrate 61, and electrodes 63 provided on the lower surface of the dielectric substrate 61. The line pattern 62a and the electrode 63 form a transmission line TL01. The line pattern 62b and the electrode 63 form a transmission line TL02. Transmission lines TL01 and TL02 correspond to impedance converters 20 and 21, respectively. The width of the transmission line TL01 in the X direction is larger than the width of the transmission line TL02 in the X direction. Thereby, the characteristic impedance of the transmission line TL01 is lower than the characteristic impedance of the transmission line TL02. Both ends of the transmission line TL01 in the Y direction correspond to ends 20a (first end) and 20b (second end) of the impedance converter 20, respectively. Both ends of the transmission line TL02 in the Y direction correspond to the ends 21a (third end) and 21b (fourth end) of the impedance converter 21, respectively. The electrodes 44, 48, 53, 63 and 68 are bonded to the base 31 by a conductive bonding layer 38 such as a brazing filler metal or a metal paste.

Bonding wires 71 electrically connect the leads 34a to 34c to the electrode 67. Bonding wires 72 electrically connect the electrode 67 and the pad 42. Bonding wires 73 electrically connect the pads 43 to the line pattern 47. Bonding wires 74 electrically connect the line pattern 47 to the electrode 52. Bonding wire 75a electrically connect the electrode 52 of the path 15a to the end 20a of the line pattern 62a. Bonding wires 75b electrically connect the electrode 52 of the path 15b to the end 20b of the line pattern 62a and the end 21a of the line pattern 62b. Bonding wires 75c electrically connect the electrode 52 of the path 15c to the end 21b of the line pattern 62b. Bonding wires 76 electrically connect the end of the line pattern 62a to the lead 35. The bonding wires 71 to 76 are metal wires such as gold wires or aluminum wires.

The bonding wires 71 and 72 function as inductors, and the capacitive component 65 functions as a capacitor. Thus, the bonding wires 71 and 72 and the capacitive component 65 correspond to each of the matching circuits 12a to 12c of the T-type LCL circuit.

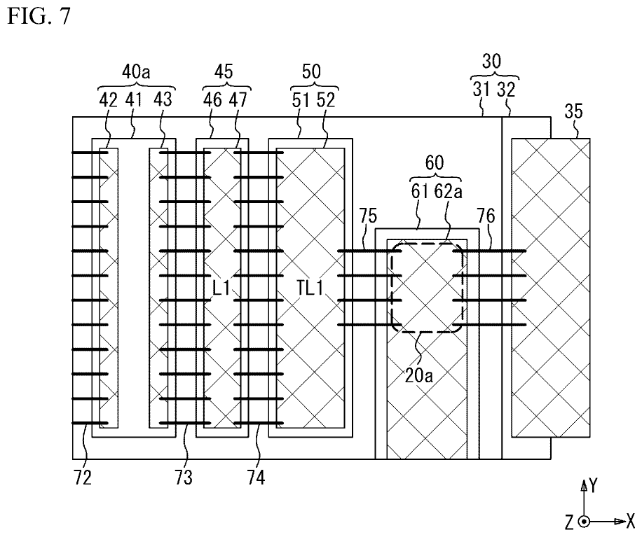

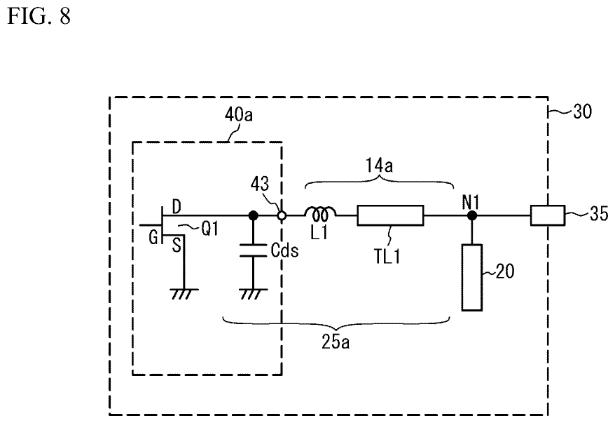

Next, the matching circuits 14a to 14c will be described by taking the matching circuit 14a as an example. The matching circuits 14b and 14c have the same configuration as the matching circuit 14a. FIG. 7 is a plan view of a part of the semiconductor device according to the first embodiment. FIG. 8 is an equivalent circuit diagram of FIG. 7. As illustrated in FIGS. 7 and 8, a drain-source capacitance is electrically connected between the pad 43 and a reference potential such as ground in the semiconductor chip 40a. Since the influences of the drain inductance Ld and the drain resistance Rd in FIG. 4 are small, the influences of the drain inductance Ld and the drain resistance Rd are ignored. An inductor L1 and a transmission line TL1 are connected in series between the pad 43 and the lead 35. The inductor L1 and the transmission line TL1 form the matching circuit 14a. The end 20a of the impedance converter 20 is connected to the node N1 between the transmission line TL1 and the lead 35.

The inductor L1 corresponds to the bonding wires 73 and 74 and the line component 45. The transmission line TL1 corresponds to the high-dielectric component 50. The drain-source capacitance Cds of the transistor Q1 and the matching circuit 14a form the impedance converter 25a.

The inductor L1 may be formed only by a bonding wire. When the inductor L1 is formed using the bonding wire, the bonding wire is made longer in order to increase the inductance of the inductor L1. In this case, the bonding wire may be fused when a large current flows through the bonding wire. Therefore, the length of the bonding wires 73 and 74 is reduced by providing the line component 45.

In order to reduce the characteristic impedance of the impedance converters 25a to 25c in FIG. 3 (for example, from 2Ω to 4Ω, the characteristic impedance of the transmission line TL1 is reduced. For example, the characteristic impedance can be adjusted by adjusting the width of the electrode 52 in the Y direction and the thickness of the high dielectric substrate 51, and the phase can be adjusted by adjusting the width of the electrode 52 in the X direction.

As described above, the characteristic impedances of the matching circuits 14a to 14c can be reduced. As a method of reducing the characteristic impedance of the matching circuits 14a to 14c, first to third comparative examples will be described.

### First Comparative Example

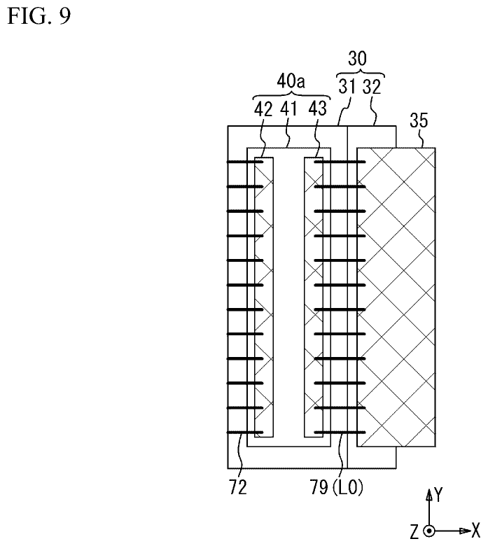

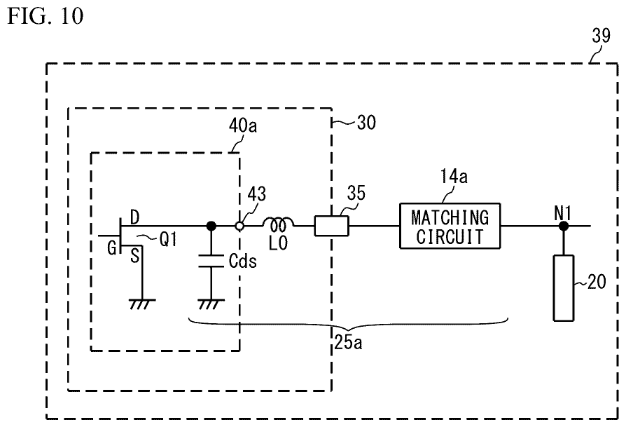

FIG. 9 is a plan view of a part of a semiconductor device according to the first comparative example. FIG. 10 is an equivalent circuit diagram of FIG. 9. As illustrated in FIG. 9, in the first comparative example, bonding wires 79 are provided to connect the pad 43 to the lead 35. As illustrated in FIG. 10, an inductor L0 is connected between the pad 43 and the lead 35. The matching circuit 14a and the impedance converter 20 are provided on a circuit substrate 39 on which the package 30 is mounted. The inductor L0 corresponds to the bonding wires 79.

When the matching circuits 14a to 14c are provided on the circuit substrate 39 on which the semiconductor device 102 is mounted as in the first comparative example, if a transmission line having a low characteristic impedance is provided on the circuit substrate, the width of the line becomes wider. This is because the dielectric substrate of the circuit substrate 39 has a relatively low dielectric constant and is thick. For example, the width of the line is about 40 mm. This increases the size of the circuit substrate. If the characteristic impedance of the matching circuit 14a is increased (for example, to 10Ω), the band of the matching circuit 14a is narrowed. If a line having a wide width is used, the width of the line for connecting the matching circuits 14a to 14c to the impedance converter 20 also becomes wide. If a shunt capacitor is used without using the line, resonance occurs due to inductances of vias of the circuit substrate 39 for shunt connection. The characteristic impedances of the impedance converters 20 and 21 need not be as low as the characteristic impedances of the matching circuits 14a to 14c. However, when the impedance converters 20 and 21 are provided on the circuit substrate 39, the following problems occur as shown in second and third comparative examples.

### Second Comparative Example

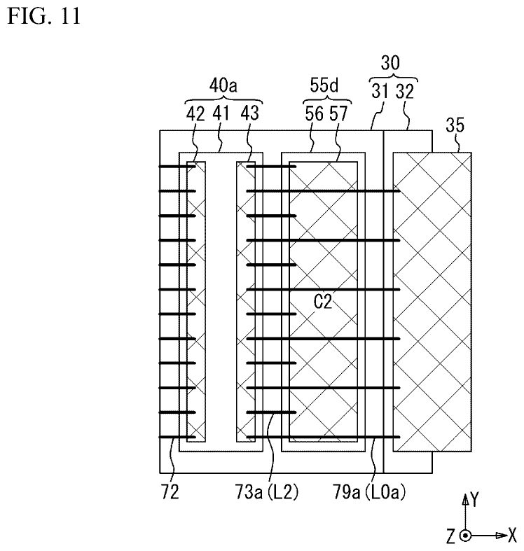

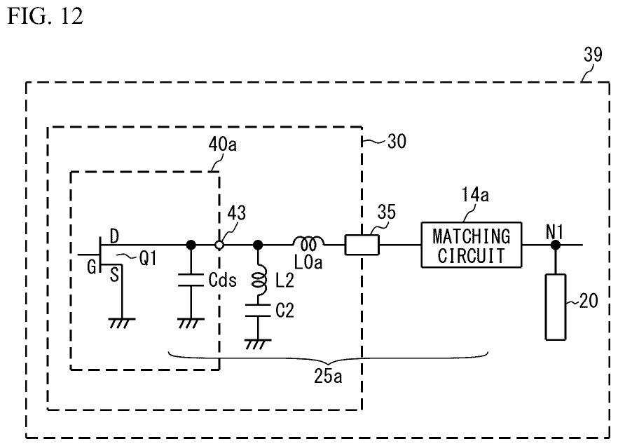

FIG. 11 is a plan view of a part of a semiconductor device according to a second comparative example. FIG. 12 is an equivalent circuit diagram of FIG. 11. As illustrated in FIG. 11, in the second comparative example, a capacitive component 55d is mounted on the base 31. Provided are bonding wires 73a for connecting the pad 43 to the electrode 56 of the capacitive component 55d, and bonding wires 79a for connecting the pad 43 to the lead 35.

As illustrated in FIG. 12, an inductor L2 connected in shunt and a capacitor C2 connected in series with the inductor L2 are provided. An inductor L0a is provided between the pad 43 and the lead 35. The inductor L2 is an inductor for compensating the drain-source capacitance Cds. The inductance of the inductor L2 is 1/((2×π×f0)²×Cds). The “f0” is a center frequency of the operating band. The capacitor C2 cuts off the direct current. The matching circuit 14a and the impedance converter 20 are provided on the circuit substrate 39. The inductors L2 and L0a correspond to the bonding wires 73a and 79a, respectively. The capacitor C2 corresponds to the capacitive component 55d.

In the second comparative example, in order to compensate the drain-source capacitance Cds by providing the inductor L2, the impedance converter 25a for shifting the phase by 90° may be provided in the pad 43 and the subsequent portions. However, since the bonding wire 79a passes over the capacitive component 55d, the inductance of the inductor L0a becomes larger than the inductance of the inductor L0 of the first comparative example. When the inductance of the inductor L0a is large, it is difficult to design an impedance converter that has a desired characteristic impedance and shifts the phase by 90° by using the matching circuit 14a having the capacitor and the inductor and the inductor L0a, making it difficult to achieve the wide band.

### Third Comparative Example

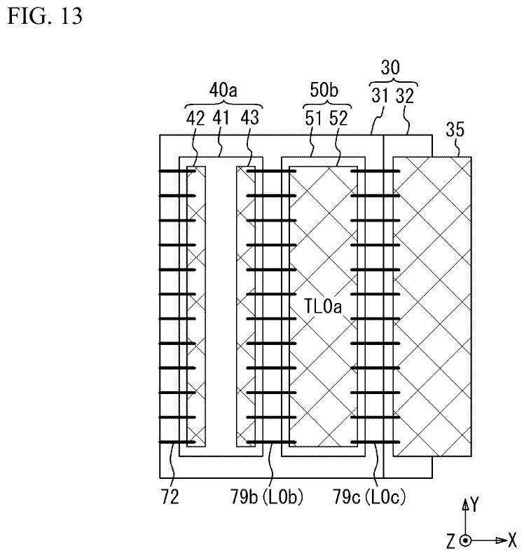

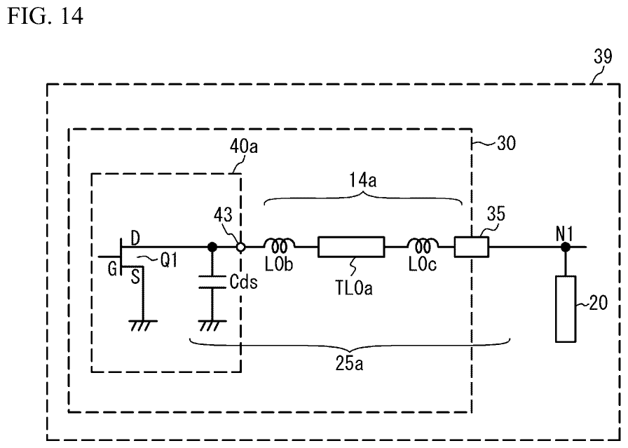

FIG. 13 is a plan view of a part of a semiconductor device according to a third comparative example. FIG. 14 is an equivalent circuit diagram of FIG. 13. As illustrated in FIG. 13, in the third comparative example, a high dielectric component 50b is mounted on the base 31. Provided are bonding wires 79b for connecting the pad 43 to the electrode 52 of the high dielectric component 50b, and bonding wires 79c for connecting the electrode 52 to the lead 35.

As illustrated in FIG. 14, an inductor L0b, a transmission line TL0a, and an inductor L0c are connected in series between the pad 43 and the lead 35. The inductor L0b, the transmission line TL0a, and the inductor L0c form the matching circuit 14a. The impedance converter 20 is provided on the circuit substrate 39. The inductors L0b and L0c correspond to the bonding wires 79b and 79c, respectively. The transmission line TL0a corresponds to the high dielectric component 50b.

In the third comparative example, the matching circuit 14a is provided in the package 30. This makes it possible to realize the matching circuit 14a having a low characteristic impedance. However, the parasitic capacitance of the lead 35 is large. Therefore, the high-frequency characteristic of the lead 35 is largely deviated from the ideal transmission line. This makes it difficult to design an impedance converter that has a desired characteristic impedance and shifts the phase by 90° using the matching circuit 14a and the lead 35, and makes it difficult to achieve a wide band.

As an example, when the center frequency f0 is 2 GHZ, the characteristic impedances of the impedance converters 20, 21, and 22 are 3.9Ω, 7.9Ω, and 11.4Ω, respectively. The characteristic impedances of the matching circuits 14a to 14c are 2.63Ω, and the shift angle of the phase is 37.2°. A description will be given of an example in which the impedance converters 20, 21 and 22 are provided on the circuit substrate 39 as in the first comparative example.

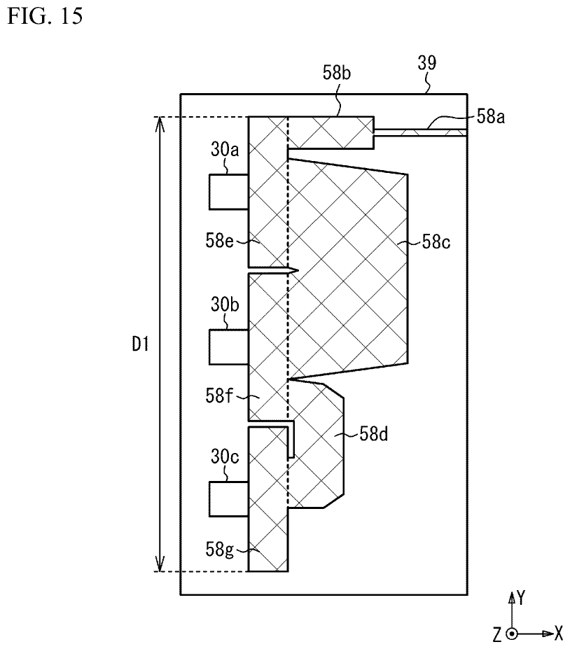

FIG. 15 is a plan view of a circuit substrate according to a first comparative example. As illustrated in FIG. 15, packages 30a to 30c are mounted on the circuit substrate 39. The main amplifier 10a and the peak amplifiers 10b and 10c are mounted in the packages 30a to 30c, respectively. Line patterns 58a to 58g are provided on the circuit substrate 39. The line pattern 58a is a line having a characteristic impedance of 50Ω. The line pattern 58b corresponds to the impedance converter 22. The line patterns 58c and 58d correspond to the impedance converters 20 and 21, respectively. The line patterns 58e to 58g correspond to the matching circuits 14a to 14c, respectively. For example, assuming that the center frequency is 2 GHz and the relative dielectric constant and thickness of the circuit substrate 39 are 3.5 and 500 μm, respectively, the length of the quarter-wavelength line is about 20 mm. The widths of the line patterns having characteristic impedances of 2.63Ω, 3.9Ω, 7.8Ω, and 11.4Ω are 35 mm, 25 mm, 12 mm, and 7.8 mm, respectively. When the line patterns 58a to 58g are provided on the circuit substrate 39, the width D1 in the Y direction is about 107 mm. Thus, the circuit substrate 39 increases in size.

### Description of First Embodiment

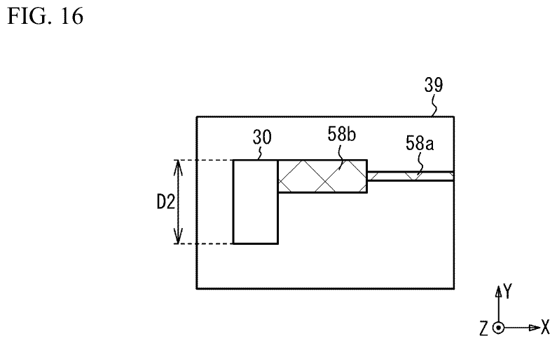

FIG. 16 is a plan view of a circuit substrate according to the first embodiment. In the first embodiment, the matching circuits 14a to 14c, and impedance converters 20 and 21 are mounted in the package 30 in addition to the main amplifier 10a and the peak amplifiers 10b and 10c. Therefore, it is sufficient to provide the line patterns 58a and 58b on the circuit substrate 39, and it is not necessary to provide the line patterns 58c to 58g. Therefore, the width D2 in the Y direction is equal to the width of the package 30, and is smaller than the width D1 of the first comparative example.

As described above, according to the first embodiment, the impedance converter 20 and the matching circuits 14a and 14b are mounted on the base 31 as illustrated in FIGS. 5 and 7. The end 20a of the impedance converter 20 is electrically connected to the pad 43 of the semiconductor chip 40a via the matching circuit 14a and electrically connected to the lead 35. The end 20b of the impedance converter 20 is electrically connected to the semiconductor chip 40b and is also electrically connected to the pad 43 of the semiconductor chip 40c via the impedance converter 21. The matching circuit 14a matches the impedances of the pad 43 of the semiconductor chip 40a and the end 20a with each other. The matching circuit 14b matches the impedances of the pad 43 of the semiconductor chip 40b and the end 20b with each other.

By mounting the impedance converter 20 and the matching circuits 14a and 14b on the base 31 in this way, the matching circuits 14a and 14b having low characteristic impedances can be realized. This allows the impedance converters 25a and 25b to shift the phase between the signal source of the transistor Q1 and the node N1 and the phase between the signal source of the transistor Q2 and the node N2 by 90°. Therefore, the N-way Doherty amplifier circuit 100 can be realized. In addition, the circuit substrate 39 can be reduced in size.

The impedance converter 21 is mounted on the base 31. The end 21a of the impedance converter 21 is electrically connected to the end 20b of the impedance converter 20, is short-circuited, and has the same potential as the end 20b of the impedance converter 20. The end 21b of the impedance converter 21 is electrically connected to the pad 43 of the semiconductor chip 40c. The matching circuit 14c matches the impedances of the pad 43 and the end 21b of the semiconductor chip 40c with each other.

By mounting the impedance converter 21 and the matching circuit 14c on the base 31 in this way, the matching circuit 14c having a low characteristic impedance can be realized. This allows the impedance converter 25c to shift the phase between the signal source of the transistor Q3 and the node N3 by 90°. Therefore, the N-way Doherty amplifier circuit 100 can be realized. The impedance converter 21 may not be necessarily provided.

The end 20a of the impedance converter 20 is electrically connected to the pad 43 of the semiconductor chip 40a via the bonding wires 73, 74, and 75a (first bonding wires). The end 20a of the impedance converter 20 is electrically connected to the lead 35 via the bonding wires 76 (second bonding wire). This allows the bonding wires 73, 74, and 75a to be used as a part of the matching circuit 14a. The bonding wires 76 may electrically connect the node N1 to the outside of the package 30.

The end 20b of the impedance converter 20 is electrically connected to the pad 43 of the semiconductor chip 40b via the bonding wires 73, 74, and 75b (third bonding wires). The end 21b of the impedance converter 21 is electrically connected to the pad 43 of the semiconductor chip 40c via the bonding wires 73, 74, and 75c (fourth bonding wires). This allows the bonding wires 73, 74 and 75b to be used as a part of the matching circuit 14b. The bonding wires 73, 74 and 75c may be used as a part of matching circuit 14c.

The impedance converter 20 includes the line pattern 62a provided on the line component 60, and the impedance converter 21 includes the line pattern 62b provided on the line component 60. This allows the transmission lines TL01 and TL02 to be used to form the impedance converters 20 and 21. By using the line patterns 62a and 62b, the characteristic impedances and the electrical lengths of the impedance converters 20 and 21 can be accurately realized.

The impedance converter 20 shifts the phase of the center frequency f0 of the operating band by 90° between the ends 20a and 20b, and the impedance converter 21 shifts the phase of the center frequency f0 of the operating band by 90° between ends 21a and 21b. Thus, the impedance converters 20 and 21 can convert the impedance on the real axis of the Smith chart into a different impedance on the real axis.

The matching circuit 14a shifts the phase of the center frequency f0 by 90° between the signal source of the main amplifier 10a and the end 20a. The matching circuit 14b shifts the phase of the center frequency f0 by 90° between the signal source of the peak amplifier 10b and the end 20b. The matching circuit 14c shifts the phase of the center frequency f0 by 90° between the signal source of the peak amplifier 10c and the end 20b. Thus, the impedance converters 25a to 25c including the matching circuits 14a to 14c, respectively, can convert the impedance on the real axis of the Smith chart into the difference impedance on the real axis.

As illustrated in FIG. 5, at the end 20a, an angle θ formed by a direction 80 in which the signal S4 flows and a direction 81 in which the signal S5 flows is about 90°. This allows the impedance converter 20 to be provided between the semiconductor chips 40a and 40b and the frame 32 so as to extend in the Y direction, thereby reducing the size of the package 30. Also at the end 20b, an angle formed by a direction in which the signal S5 flows and a direction in which the signal S6 flows is about 90°, as in the case of the above-mentioned angle θ. This allows the impedance converter 21 to be provided between the semiconductor chips 40b and 40c and the frame 32 so as to extend in the Y direction, thereby reducing the size of the package 30. The angle θ may not be 90°, and may be, for example, 70° or more and 110° or less, or 80° or more and 100° or less.

The phase of the center frequency f0 may not be exactly shifted by 90°. For example, the phase of rotation is 70° or more and 110° or less, or 85° or more and 95° or less. The impedance on the real axis does not have to be strictly on the real axis (that is, the reactance component is 0). An absolute value of a reactance component of the impedance may be 1.0 times or less or 0.2 times or less a resistance component thereof.

### Alternative Example of Impedance Converters 20 and 21

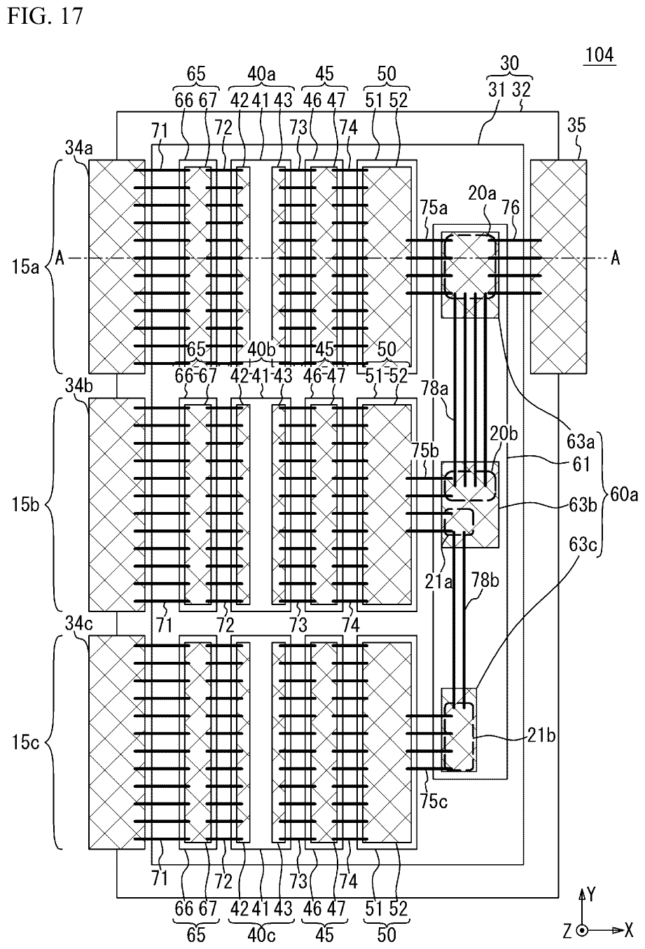

FIG. 17 is a plan view of a semiconductor device illustrating alternative example of the impedance converter in the first embodiment. As illustrated in FIG. 17, in a semiconductor device 104, a line component 60a includes electrodes 63a to 63c on the dielectric substrate 61. The electrodes 63a and 63b are electrically connected by bonding wires 78a. The electrode 63b and the electrode 63c are electrically connected by bonding wires 78b. The bonding wires 75a and 76 are connected to the electrode 63a. The bonding wires 75b and 75c are connected to the electrodes 63b and 63c, respectively.

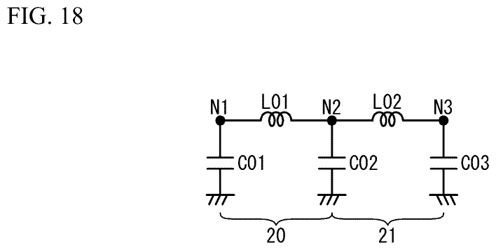

FIG. 18 is a circuit diagram illustrating alternative example of the impedance converter in the first embodiment. An inductor L01 is connected between the nodes N1 and N2, and an inductor L02 is connected between the nodes N2 and N3. Capacitors C01, C02, and C03 are shunt connected from node N1 to node N3, respectively. The capacitors C01, C02 and the inductor L01 form the impedance converter 20, and the capacitors C02, C03 and the inductor L02 form the impedance converter 21. The capacitors C01, C02, and C03 correspond to the electrodes 63a to 63c sandwiching the dielectric substrate 61 and the base 31, respectively. The inductors L01 and L02 correspond to the bonding wires 78a and 78b, respectively.

Assume that the target characteristic impedances of the impedance converters 20 and 21 are Z01 and Z02, respectively, the capacitances of the capacitors C01 to C03 are C01 to C03, respectively, and the inductances of the inductors L01 and L02 are L01 and L02, respectively. Here, L01=Z01/(2×π×f0), L02=Z02/(2×π×f0), C01=(2×π×f0)/Z01, C02=(2×π×f0)/Z01+(2×π×f0)/Z02, and C03=(2×π×f0)/Z02 are set. This allows the characteristic impedances Z01 and Z02 of the impedance converters 20 and 21 to be set to target values.

As illustrated in FIGS. 17 and 18, the impedance converter 20 may include the capacitors C01 (first capacitor), C02 (second capacitor), and the bonding wires 78a (fifth bonding wire). The first ends of the capacitors C01 and C02 are electrically connected to the base 31. The bonding wires 78a electrically connect the second end of the capacitor C01 to the second end of the capacitor C02. The impedance converter 21 may include the capacitors C02, C03 and the bonding wires 78b. The first ends of the capacitors C02 and C03 are electrically connected to the base 31. The bonding wires 78b electrically connect the second end of the capacitor C02 to the second end of the capacitor C03. This allows the impedance converters 20 and 21 to be formed. Although the example in which the electrodes 63a to 63c are provided on one dielectric substrate 61 has been described, the electrodes 63a to 63c may be provided on different dielectric substrates 61.

### First Alternative Example of Matching Circuits 14a to 14c

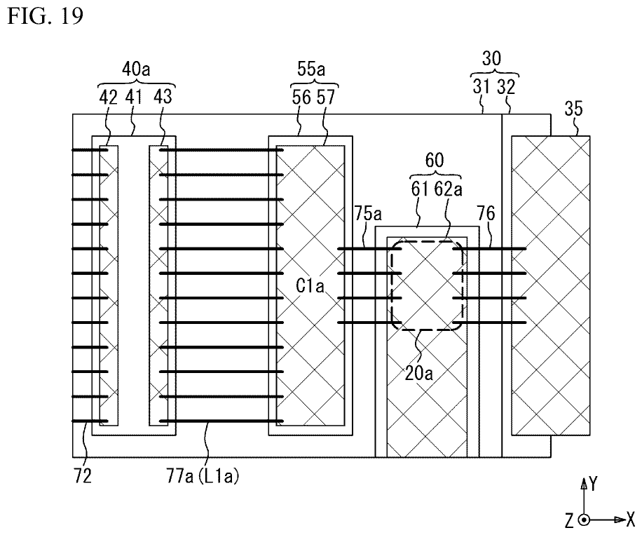

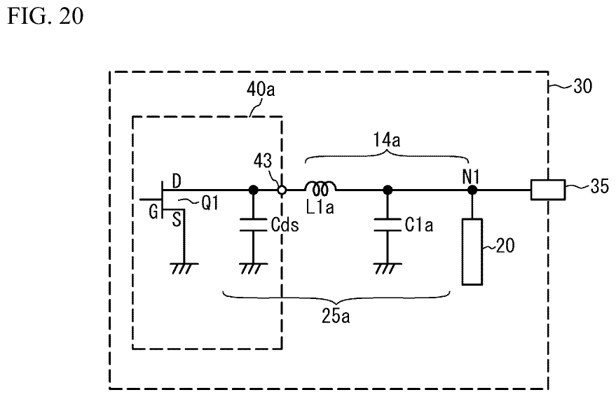

Although the matching circuit 14a is described as an example of the matching circuits 14a to 14c, the matching circuits 14b and 14c can be formed in the same manner. The same applies to second to fourth alternative examples of the matching circuits 14a to 14c described later. FIG. 19 is a plan view illustrating a first alternative example of the matching circuit in the first embodiment. FIG. 20 is an equivalent circuit diagram of FIG. 19. As illustrated in FIG. 19, in the first alternative example of the matching circuit 14a, a capacitive component 55a is mounted on the base 31. Provided are bonding wires 77a for electrically connecting the pad 43 and an electrode 57 of the capacitive component 55a, and the bonding wires 75a for electrically connecting the electrode 57 and the end 20a.

As illustrated in FIG. 20, an inductor L1a for connecting the pad 43 to the node N1, and a capacitor C1a for shunt connection between the inductor L1a and the node N1 are provided. The inductor L1a corresponds to the bonding wires 77a. The capacitor C1a corresponds to the capacitive component 55a.

When the capacitance of the capacitor C1a is the same as the drain-source capacitance Cds and the inductance of the inductor L1a is 1/((2×π×f0)²×Cds), the impedance converter 25a shifts the phase of the center frequency f0 by 90°. The characteristic impedance of the impedance converter 25a is 1/(2×π×f0×Cds). In the first alternative example of the matching circuits 14a to 14c, the characteristic impedance cannot be set freely, but the number of components mounted on the base 31 can be reduced.

### Second Alternative Example of Matching Circuits 14a to 14c

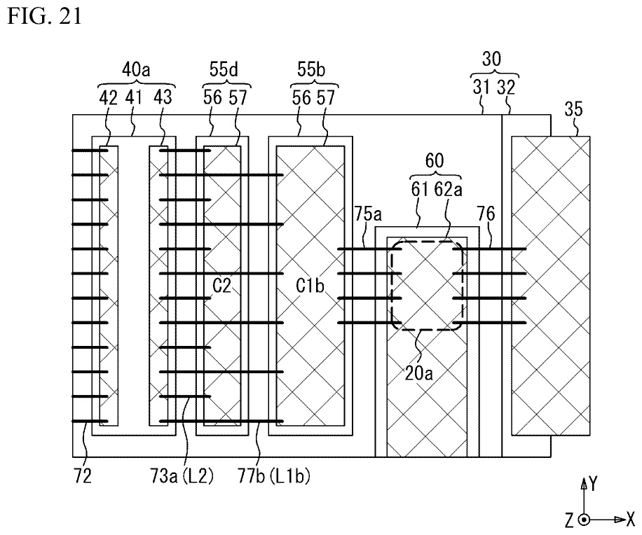

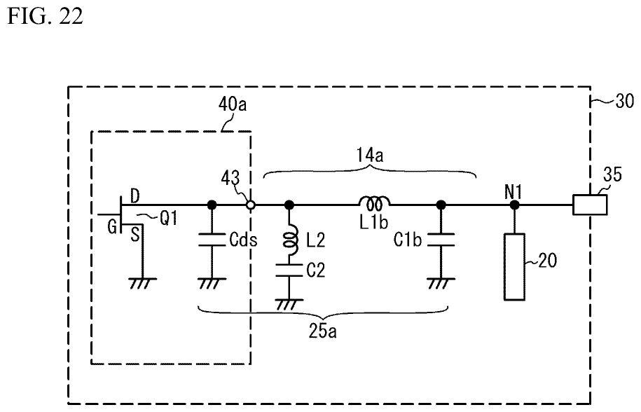

FIG. 21 is a plan view illustrating a second alternative example of the matching circuit in the first embodiment. FIG. 22 is an equivalent circuit diagram of FIG. 21. As illustrated in FIG. 21, in the second alternative example of the matching circuit 14a, the capacitive components 55d and 55b are mounted on the base 31. Provided are the bonding wires 73a for electrically connecting the pad 43 to the electrode 57 of the capacitive component 55d, the bonding wires 77b for electrically connecting the pad 43 to the electrode 57 of the capacitive component 55b, and the bonding wires 75a for electrically connecting the electrode 57 of the capacitive component 55b to the end 20a.

As illustrated in FIG. 22, the inductor L2 is shunt-connected, and the capacitor C2 is connected in series to the inductor L2. An inductor L1b for connecting the pad 43 and the node N1, and a capacitor C1b for shunt connection between the inductor L1b and the node N1 are provided. The inductors L2 and L1b correspond to the bonding wires 73a and 77b, respectively. The capacitors C2 and C1b correspond to the capacitive components 55d and 55b, respectively.

The inductance of the inductor L2 is greater than 1/((2×π×f0)²×Cds). As a result, the inductor L2 does not fully compensate the drain-source capacitance Cds. An uncompensated capacitance component is assumed to be ΔCds. The capacitor C2 is a DC cut capacitor, and the capacitance is sufficiently large not to affect inductor L2 at center frequency f0. The inductance of the inductor L1b is 1/(2×π×f0)²×(Cds−ΔCds), and the capacitance of the capacitor C1b is “Cds−ΔCds”. As a result, the impedance converter 25a shifts the phase of the center frequency f0 by 90°. The characteristic impedance of the impedance converter 25a is 1/(2×π×f0×(Cds−ΔCds)). By selecting the value of ΔCds in this way, the characteristic impedance of the impedance converter 25a can be set freely as compared with the case of the first alternative example.

Instead of the inductor L2 and the capacitor C2, the capacitor C2 may be provided without providing the inductor. In this case, the capacitance of the capacitor C2 is represented by ΔCds. The inductance of the inductor L1b is 1/((2×π×f0)²×(Cds+ΔCds)), and the capacitance of the capacitor C1b is Cds+ΔCds. As a result, the impedance converter 25a shifts the phase of the center frequency f0 by 90°. The characteristic impedance of the impedance converter 25a is 1/(2×π×f0×(Cds+ΔCds)). In this case, the characteristic impedance of the impedance converter 25a can be set freely.

### Third Alternative Example of Matching Circuits 14a to 14c

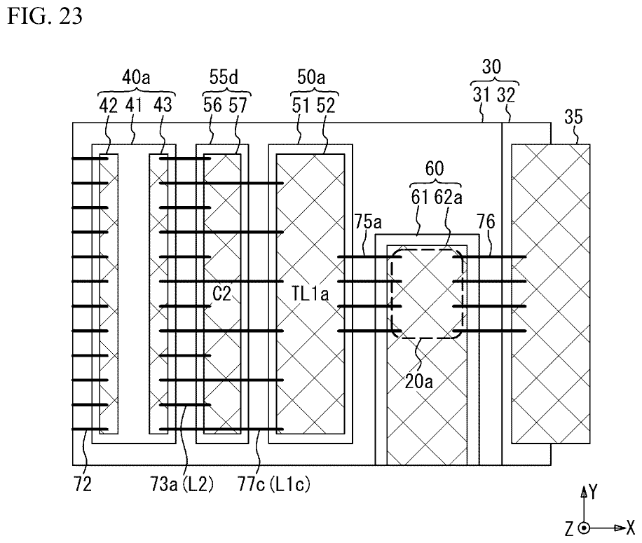

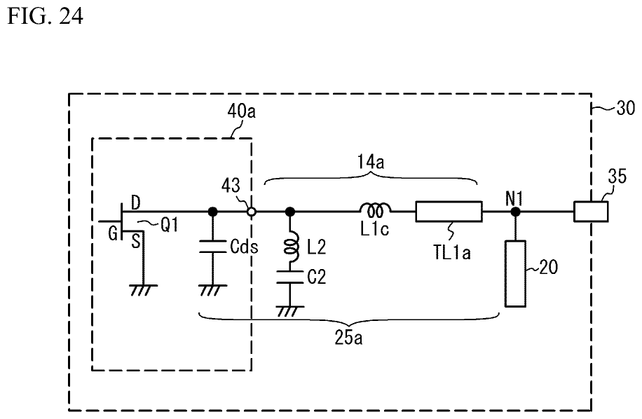

FIG. 23 is a plan view illustrating a third alternative example of the matching circuit in the first embodiment. FIG. 24 is an equivalent circuit diagram of FIG. 23. As illustrated in FIG. 23, in third alternative example of the matching circuit 14a, the capacitive component 55d and a high dielectric component 50a are mounted on the base 31. Provided are the bonding wires 73a for electrically connecting the pad 43 to the electrode 57 of the capacitive component 55d, bonding wire 77c for electrically connecting the pad 43 to the electrode 52 of the high dielectric component 50a, and the bonding wires 75a for electrically connecting the electrode 52 of the high dielectric component 50a and the end 20a.

As illustrated in FIG. 24, the inductor L2 is shunt-connected, and the capacitor C2 is connected in series to the inductor L2. An inductor L1c and a transmission line TL1a are connected in series between the pad 43 and the node N1. The inductors L2 and L1c correspond to the bonding wires 73a and 77c, respectively. The capacitor C2 corresponds to the capacitive component 55d. The transmission line TL1a corresponds to the high dielectric component 50a.

The inductance of the inductor L2 is 1/(2×π×f0)²×Cds). Thus, the inductor L2 compensates for the drain-source capacitance Cds. The phase of the center frequency f0 may be shifted by 90° by using the inductor L1c and the transmission line TL1a. The characteristic impedance of the transmission line TL1a and the phase to be shifted can be set in the same manner as in the high dielectric component 50 illustrated in FIGS. 7 and 8. Since the drain-source capacitance Cds is compensated in this way, the phase to be shifted by the transmission line TL1a only needs to be set to around 90°, which facilitates the design of the high dielectric component 50a.

### Fourth Alternative Example of Matching Circuits 14a to 14c

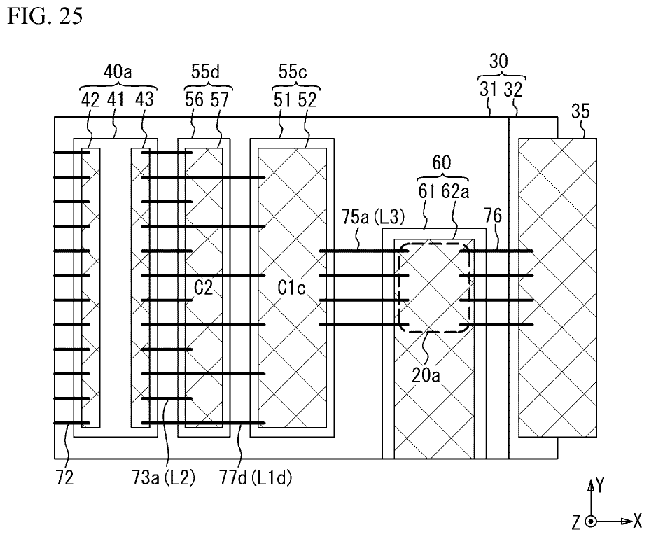

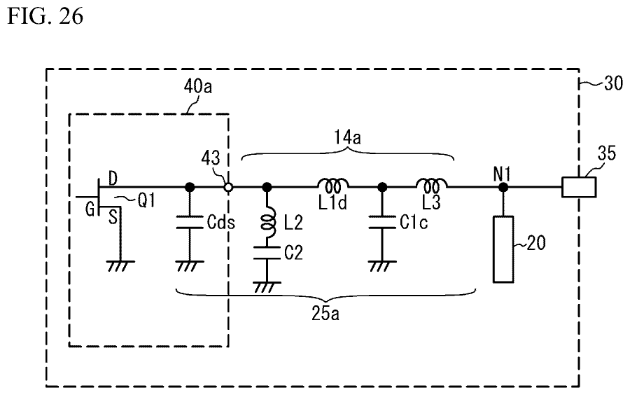

FIG. 25 is a plan view illustrating a fourth alternative example of the matching circuit in the first embodiment. FIG. 26 is an equivalent circuit diagram of FIG. 25. As illustrated in FIG. 25, in the fourth alternative example of the matching circuit 14a, the capacitive component 55d and a capacitive component 55c are mounted on the base 31. Provided are the bonding wires 73a for electrically connecting the pad 43 and the electrode 57 of the capacitive component 55d, bonding wires 77d for electrically connecting the pad 43 and the electrode 52 of the capacitive component 55c, and the bonding wires 75a for electrically connecting the electrode 52 of the capacitive component 55c and the end 20a.

As illustrated in FIG. 26, the inductor L2 is connected by shunt, and the capacitor C2 is connected in series to the inductor L2. Inductors L1d and L3 are connected in series between the pad 43 and the node N1. A capacitor C1c is shunt-connected to a node between the inductors L1d and L3. The inductors L2, L1d and L3 correspond to the bonding wires 73a, 77d and 75a, respectively. The capacitors C2 and C1c correspond to the capacitive components 55d and 55c, respectively.

The inductance of the inductor L2 is 1/((2×π×f0)²×Cds). Thus, the inductor L2 compensates for the drain-source capacitance Cds. The phase of the center frequency f0 may be shifted by 90° by using the inductors L1d and L3 and the capacitor C1c. For example, when the characteristic impedance of the impedance converter 25a is Z0, the inductances of the inductors L1d and L3 are set to Z0/(2×π×f0), and the capacitance of the capacitor C1c is set to 1/(2×π×f0×Z0). In this way, the drain-source capacitance Cds is compensated, which facilitates the design of the inductors L1d and L3 and the capacitor C1c.

Although the first embodiment has been described as an example in which the semiconductor substrates 41 of the semiconductor chips 40a to 40c are separated from each other, at least two of the semiconductor substrates 41 of the semiconductor chips 40a to 40c may be provided as a common integral body.

Although the 3-way Doherty amplifier circuit has been described as an example, in the case of an N-way Doherty amplifier circuit, N semiconductor chips, N matching circuits, and N−1 impedance converters may be provided.

Although the saturation powers of the main amplifier 10a and the peak amplifiers 10b and 10c are the same as each other, the saturation powers of the main amplifier 10a and the peak amplifiers 10b and 10c may be different from each other. For example, the saturation power of the peak amplifiers 10b and 10c may be twice that of the main amplifier 10a.

The embodiments disclosed here should be considered illustrative in all respects and not restrictive. The present disclosure is not limited to the specific embodiments described above, but various variations and changes are possible within the scope of the gist of the present disclosure as described in the claims.

1. A semiconductor device comprising:
a package that includes a base and an output lead;
a first semiconductor chip that is mounted on the base and includes a main amplifier for amplifying a first signal into which an input signal is divided and a first output pad for outputting an amplified first signal;
a second semiconductor chip that is mounted on the base and includes a first peak amplifier for amplifying a second signal into which the input signal is divided and a second output pad for outputting an amplified second signal;
a third semiconductor chip that is mounted on the base and includes a second peak amplifier for amplifying a third signal into which the input signal is divided and a third output pad for outputting an amplified third signal;
a first impedance converter that is mounted on the base, and has a first end electrically connected to the first output pad and the output lead, and a second end electrically connected to the second output pad and the third output pad;
a first matching circuit that is mounted on the base, and matches impedances of the first output pad and the first end with each other; and
a second matching circuit that is mounted on the base, and matches impedances of the second output pad and the second end with each other.

2. The semiconductor device according to claim 1, further comprising:
a second impedance converter that is mounted on the base, and has a third end electrically connected to the second end of the first impedance converter, and a fourth end electrically connected to the third output pad; and
a third matching circuit that matches impedances of the third output pad and the fourth end with each other.

3. The semiconductor device according to claim 1, wherein
the first end is electrically connected to the first output pad via a first bonding wire, and
the first end is electrically connected to the output lead via a second bonding wire.

4. The semiconductor device according to claim 3, wherein
the second end is electrically connected to the second output pad via a third bonding wire.

5. The semiconductor device according to claim 2, wherein
the first end is electrically connected to the first output pad via a first bonding wire,
the second end is electrically connected to the output lead via a second bonding wire,
the second end and the third end are electrically connected to the second output pad through a third bonding wire, and
the fourth end is electrically connected to the third output pad via a fourth bonding wire.

6. The semiconductor device according to claim 1, further comprising:
a line component including a dielectric substrate mounted on the base and a line pattern provided on the dielectric substrate,
wherein the first impedance converter includes the line pattern.

7. The semiconductor device according to claim 1, further comprising:
a first capacitor that is mounted on the base and has a first end electrically connected to the base;
a second capacitor that is mounted on the base and has a first end electrically connected to the base; and
a fifth bonding wire that electrically connects a second end of the first capacitor to a second end of the second capacitor;
wherein the first impedance converter includes the first capacitor, the second capacitor, and the fifth bonding wire.

8. The semiconductor device according to claim 1, wherein
the first impedance converter shifts a phase of a center frequency of an operating band by 90° between the first end and the second end.

9. The semiconductor device according to claim 8, wherein
the first matching circuit shifts the phase of the center frequency by 90° between a signal source of the main amplifier and the first end, and
the second matching circuit shifts the phase of the center frequency by 90° between a signal source of the first peak amplifier and the second end.

10. The semiconductor device according to claim 2, wherein
the first impedance converter shifts a phase of a center frequency of an operating band by 90° between the first end and the second end,
the second impedance converter shifts a phase of a center frequency of an operating band by 90° between the third end and the fourth end,
the first matching circuit shifts the phase of the center frequency by 90° between a signal source of the main amplifier and the first end,
the second matching circuit shifts the phase of the center frequency by 90° between a signal source of the first peak amplifier, and the second end and the third end, and
the third matching circuit shifts the phase of the center frequency by 90° between a signal source of the second peak amplifier and the fourth end.

11. The semiconductor device according to claim 1, wherein
an input power for turning on the first peak amplifier is larger than an input power for turning on the main amplifier, and
an input power for turning on the second peak amplifier is larger than the input power for turning on the first peak amplifier.

12. The semiconductor device according to claim 1, wherein
an angle formed between a direction in which the amplified first signal flows and a direction in which the amplified second signal flows is 70° or more and 110° or less at the first end.

13. A Doherty amplifier circuit comprising:
the semiconductor device according to claim 1; and
a divider that divides the input signal into the first signal, the second signal, and the third signal.
